(19) United States
(12) Patent Application Publication
(10) Pub. No.: US 2006/0174827 A1
(43) Pub. Date: Aug. 10, 2006

(54) Apparatus for manufacturing semiconductor device

(76) Inventors: Byoung-Jae Bae, Gyeonggi-do (KR); Ji-Eun Lim, Seoul (KR); Yeon-Kyu Jung, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/329,451

(22) Filed: Jan. 10, 2006

(30) Foreign Application Priority Data
Jan. 10, 2005 (KR) 2005-02280

(51) Int. Cl. C30B 11/00

(52) U.S. Cl. 117/200; 117/900

(57) ABSTRACT

A deposition apparatus is provided that has a reaction-chamber, a wafer support, gas supply line, an ejection unit and a diffusion unit. The ejection unit includes a bottom portion spaced apart from a top wall of the reaction chamber to form a space. The diffusion unit is positioned below the gas supply line and includes a planar portion having upwardly extending flanges forming an upwardly open space below the gas supply line. Gas flowing from the gas supply line flows into the upwardly open space and ascends the upwardly extending flanges to diffuse the gas into the space.

### CROSS-REFERENCE TO RELATED APPLICATIONS

This U.S. non-provisional patent application claims priority under 35 U.S.C. § 119 of Korean Patent Application No. 2005-02280 filed on Jan. 10, 2005, the entire contents of which are hereby incorporated by reference.

### BACKGROUND

The present invention relates to semiconductor manufacturing apparatuses, and more particularly to apparatuses for depositing films on substrates.

Manufacturing semiconductor devices utilizes a variety of processing techniques such as deposition, photolithography, etching and ion implantation. The deposition process is carried out to form a film on a wafer where one or more gases are supplied into a reaction chamber at the same time or in sequence while the temperature and pressure in the chamber are regulated.

A general deposition apparatus has a reaction chamber including a support onto which wafers are mounted and a shower head that supplies a processing gas to the wafers. The processing gas is supplied through ejection holes in an ejection plate that is in a center space near a top wall of the chamber. However, as the processing gas is supplied downward through the ejection plate, it is not sufficiently diffused in the shower head and causes an insufficient deposition rate at the edges of the wafer. As a result, the ejection plate is positioned far away from the wafer, so much so that the gas must be supplied in an excessive amount. Such a problem may become worse in proportion to the size of the wafer.

Meanwhile, the ejection plate typically utilizes cooling and heating lines for maintaining a temperature of the processing gas in the shower head. It is important to place the ejection holes in a manner that will regularly supply the processing gas over the wafer, but the cooling and heating lines act as limits to the proper placement of the ejecting holes.

Furthermore, the ejection plate in the shower head should correspond to the size of the wafer in order to obtain the required deposition uniformity and rate.

### SUMMARY OF THE DISCLOSURE

A semiconductor device manufacturing apparatus includes a reaction chamber, a wafer support, an ejection unit and a diffusion unit located below a first gas supply line to diffuse a first gas supplied to diffusion unit. The ejection unit has an ejection plate in a bottom portion of the ejection unit with ejection holes through the ejection plate. The bottom portion of the ejection unit is spaced apart from a top wall of the reaction chamber to form a first space. The diffusion unit includes a planar diffusion plate having upwardly extending flanges forming an upwardly open space below the first gas supply line such that the first gas from the first gas supply line flows into the upwardly open space and ascends the upwardly extending flanges to diffuse the first gas into the first space.

Another semiconductor device manufacturing apparatus includes a reaction chamber, a wafer support, a first gas supply line to supply a first processing gas and a gas diffusion unit to diffuse the first processing gas over the wafer support. The gas diffusion unit includes a first diffusion plate and a second diffusion plate. The first diffusion plate is spaced apart from a top wall of the reaction chamber to form a first space. The first diffusion plate includes first distribution holes through the first diffusion plate located near and edge of the first space. The second diffusion plate is space apart from a bottom surface of the first diffusion plate to form a second space. The second diffusion plate includes second outer distribution holes through the second diffusion plate located near an edge of the second space.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention. In the drawings:

FIG. 1 is a cross-sectional diagram of a deposition apparatus;

FIG. 2 is a graph showing the endurance of a ferroelectric memory device versus the sensing margin of the device when heated at 150° C. for varying distances between a wafer and an ejection unit;

FIG. 3 is a graph showing a deposition rate versus a distance between a wafer and an ejecting unit at varying processing pressures;

FIG. 4 is a perspective diagram illustrating a diffusion unit;

FIG. 5 is a cross-sectional diagram of the diffusion unit shown in FIG. 4;

FIG. 6 is a top plan view of the diffusion unit shown in FIG. 4;

FIGS. 7 and 8 are perspective diagrams illustrating other of the diffusion units;

FIG. 9 is a cross-sectional diagram illustrating another diffusion unit;

FIG. 10 is a perspective diagram illustrating another diffusion unit;

FIG. 11 is a top plan view of the diffusion unit shown in FIG. 10;

FIG. 12 is a cross-sectional diagram illustrating another diffusion unit;

FIG. 13 is a bottom plan view of a plurality of diffusion units arranged in a reaction chamber;

FIG. 14 is a cross-sectional diagram illustrating an ejection unit with a gas diverting projection;

FIG. 15 is a cross-sectional diagram illustrating a flow of processing gas in the ejection unit shown in FIG. 14;

FIG. 16 is a cross-sectional diagram illustrating a flow of processing gas in another ejection unit;

FIG. 17 is a cross-sectional diagram illustrating an a gas supplier with a diffusion unit;

FIG. 18 is a cross-sectional diagram illustrating another diffusion unit;

FIG. 19 is a top plan view of a first diffusion plate;

FIG. 20 is a top plan view of a second diffusion plate and a partition;

FIG. 21 is a top plan view of a third diffusion plate and partitions;

FIG. 22 is a cross-sectional diagram illustrating a flow of processing gas in the diffusion unit shown in FIG. 18;

FIG. 23 is a cross-sectional diagram showing a supply line disposed in the top wall of a chamber;

FIG. 24 is a cross-sectional diagram illustrating an a gas supplier with a distributor; and

FIG. 25 is a perspective diagram of the distributor shown in FIG. 24.

### DETAILED DESCRIPTION

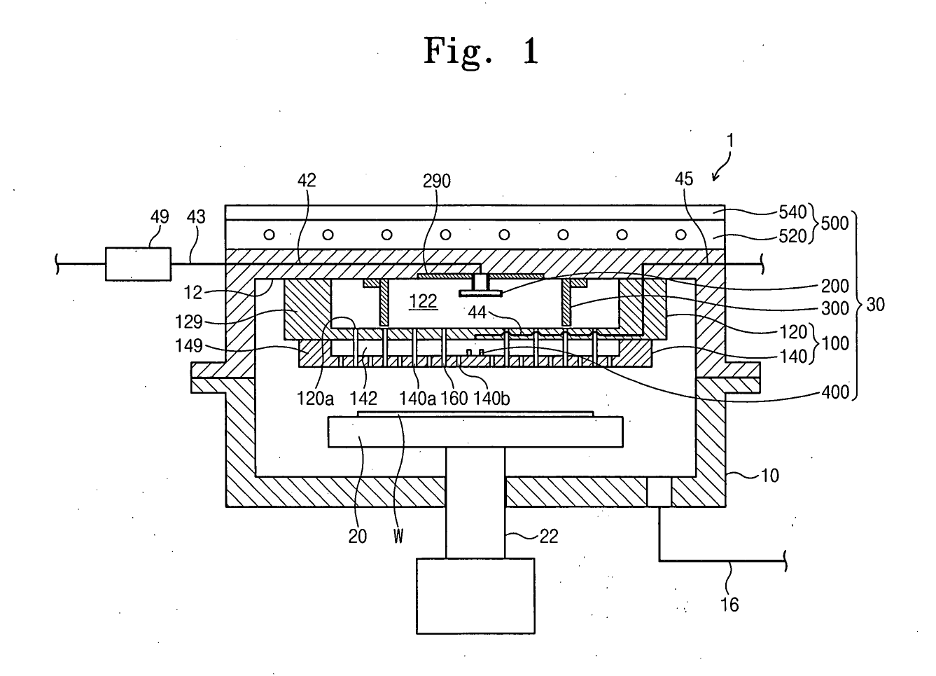

Preferred embodiments of the present invention will be described below in more detail with reference to the accompanying drawings FIGS. 1 through 25. The present invention may, however, be embodied in different forms and should not be constructed as limited to the embodiments set forth herein. Rather, these embodiments are provided so that this disclosure will be thorough and complete, and will fully convey the scope of the invention to those skilled in the art.

In the drawings, the thickness of layers and regions are exaggerated for clarity. It will also be understood that when a layer is referred to as being on another layer or substrate, it can be directly on the other layer or substrate, or intervening layers may also be present. Like numerals refer to like elements throughout the specification.

These embodiments will be exemplarily described about a metal organic chemical vapor deposition apparatus, while the invention may not be limited on them and applicable to deposition apparatuses of forming films on wafers by means of processing techniques with chemical vapor deposition or atomic layer deposition, or all kinds of apparatuses prosecuting deposition processes by supplying gases to wafers with using ejection plates.

FIG. 1 is a cross-sectional diagram of a metal organic chemical vapor deposition (MOCVD) apparatus 1. Referring to FIG. 1, the MOCVD apparatus 1 includes a reaction chamber 10 that has an internal space. A vent 16 connected to a pump (not shown) is connected to a sidewall or to the bottom of the chamber 10. The vent 16 maintains the pressure of the internal space at a level appropriate for processing and exhausts byproducts out of the chamber 10.

At the bottom of the chamber 10, a support 20 is disposed for mounting a semiconductor substrate such as a wafer W. The support 20 is the shape of a round plate supported by axis 22. The support 20 rotates on the supporting axis 22. The support 20 includes an internal heater (not shown). The heater dissolves a processing gas supplied to the wafer W and provides heat to the chamber 10 in order to smoothly deposit the processing gas on the wafer W. At the top of the chamber 10, a gas supplier 30 is disposed to supply the processing gas to the wafer W. The gas supplier 30 is positioned to be opposite to the support 20.

The gas supplier 30 in the chamber 10 is connected to external conduits that introduce the processing gases to the gas supplier. A first processing gas is introduced to the gas supplier 30 by way of a first conduit 43, while a second processing gas is introduced to the gas supplier 30 by way of a second conduit 45. According to this embodiment, the first processing gas is composed of a gaseous material, having low vapor pressure and existing in liquid or solid phase at room temperature, and which contains a metal organic precursor gas supplied in a vaporized state. The second processing gas may be a gaseous material at room temperature for reacting with the first processing gas. For example, in the case of depositing a film of plumbum-zirconium-titanium oxide (PZT; PbZrTiO₃) on the wafer W, the first processing gas contains plumbum (Pb), zirconium (Zr), and titanium (Ti) and the second processing gas contains oxygen (O). At the first conduit 43, an evaporator 49 is connected to a tube to supply a carrier gas carrying an evaporated metal organic precursor gas or to a tube (not shown) to supply a purge gas. Each of the conduits 43 and 45 may be comprised of a switching valve (not shown) to shut its internal path on or off, and a flux control valve (not shown) to regulate the quantity of gas flow.

The gas supplier 30 has an ejection unit 100 and a diffusion unit 200. The ejection unit 100 is constructed of a first ejection plate 120 and a second ejection plate 140. The first ejection plate 120 is round in shape and includes a sidewall 129 protruded upward in the shape of ring from the edge of the ejection plate 120. Thus, it results in an upwardly open space at the center of the first ejection plate 120. The sidewall 129 contacts the top wall of the chamber 10.

The second ejection plate 140 is positioned under the first ejection plate 120. The second ejection plate 140 is round in shape and includes a sidewall 149 protruded upward in the shape of ring from the edge of the ejection plate 140. Thus, it results in generation an upwardly open space at the center of the second ejection plate 140. The first and the second ejection plates 120, 140 are fixed to the top wall of the chamber 10 by means of jointing units (not shown) such as screws that penetrate the sidewalls 129, 149.

A first introductive space 122 is defined as a space surrounded by the first ejection plate 120 and the top wall 12 of the chamber 10, while a second introductive space 142 is defined as a space surrounded by the first and second ejection plates 120 and 140. The first processing gas flows into the first introductive space 122, while the second processing gas flows into the second introductive space 142. Pluralities of first holes 120a are formed in the first ejection plate 120. Pluralities of second holes 140a are formed in the second ejection plate 140, opposite to the first holes 120a. Pluralities of third holes 140b are formed in spaces between the second holes 140a. Ejection tubes 160 are inserted between each of the first and second holes 120a and 140a opposite to each other. The first processing gas flowing into the first introductive space 122 jets downward through the ejection unit 100 through the ejection tubes 160, while the second processing gas flowing into the second introductive space 142 jets downward through the ejection unit 100 through the third holes 140b.

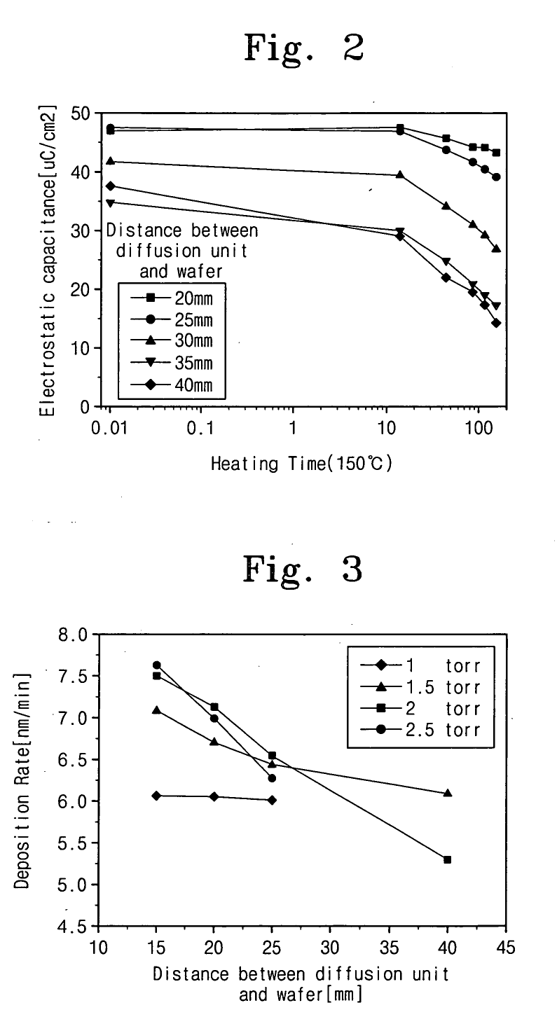

In a current apparatuses, the processing gas jets downward through the ejection unit prior to being sufficiently diffused within the ejection unit. Because of that, the spacing between the ejection unit 100 and the wafer W is longer and a large amount of processing gas is used in order to obtain a required deposition rate at the edge of the wafer W. FIG. 2 is a graph showing the endurance of a ferroelectric memory device versus the sensing margin of the device when heated at 150° C. for varying distances between a wafer W and an ejection unit 100 while depositing a PZT film on the wafer W. FIG. 3 is a graph showing a deposition rate versus a distance between the wafer W and the ejecting unit 100 at varying processing pressures. The data in FIGS. 2 and 3 were obtained from using a wafer W with a diameter of 150 mm. Referring to FIGS. 2 and 3, the reliability of the sensing margin and the deposition rate improve as the deposition process is carried out with a narrower spacing between the wafer W and the ejection unit 100.

In this embodiment of the present invention, the interval between the ejection unit 100 and the wafer W mounted on the supporting structure is designed to be minimized in order to improve the deposition rate and the sensing margin. The diffusion unit 200 diffuses the processing gas supplied into the first introductive space 122 in order to prevent the processing gas from concentrating on the center of the wafer W. It is preferable for the interval between the wafer W and the ejection unit 100 to be within about 20 mm.

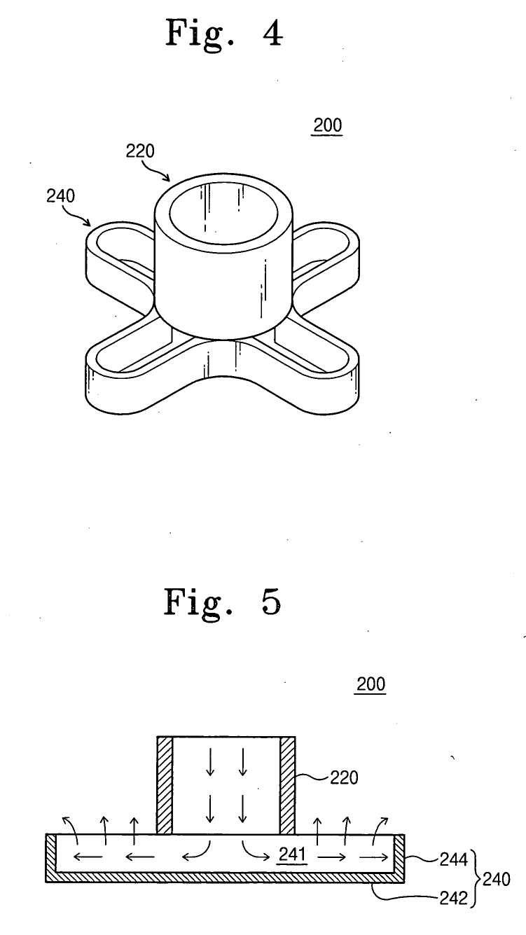

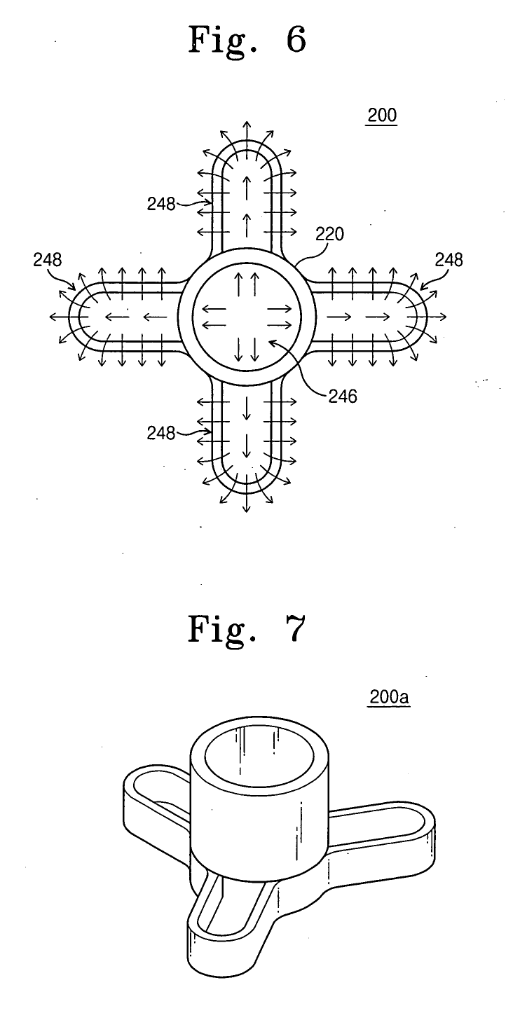

FIG. 4 is a perspective diagram illustrating the diffusion unit 200. FIG. 5 is a cross-sectional view of the diffusion unit 200 and FIG. 6 is a top plan view of the diffusion unit 200, showing the flow of the processing gas in the diffusion unit 200. Referring to FIGS. 4 and 6, the diffusion unit 200 is disposed within the first introductive space 122, diffusing the first processing gas flowing into the first introductive space 122 along the supply line 42 that is positioned within the top wall 12 of the chamber 10. The diffusion unit 200 includes an introductive tube 220 and a diffusion plate 240. The introductive tube 220 is connected to the supply line 42. The top wall 12 of the chamber 10 includes a depressed portion into which a combination plate 290 with the introductive tube 220 is inserted, as shown in FIG. 1. The combination plate 290 is joined with the chamber 10 by joining means such as screws. The diffusion plate 240 is coupled to the bottom end of the introductive tube 220. The diffusion plate 240 has a bottom plane 242 that is mostly flat, and a fringe face 244 protruding upward from the edge of the bottom plane 242. Thus, there is an upwardly open space at the center of the diffusion plate 240.

The diffusion plate 240 also includes a central part 246 sized similarly to an outlet of the introductive tube 220, and laterally elongated extension parts 248. The introductive tube 220 is affixed to the diffusion plate 240 at the boundary between the central part 246 and the extension parts 248. The introductive tube 220 may be affixed to the diffusion plate 240 by various means such as adhesive agents or screws, or may be manufactured as a single body together with the diffusion plate 240. The extension parts 248 are spaced from each other a predetermined distance, providing spaces for gas flow therebetween. For instance as shown in FIG. 4, four extension parts 248 are arranged at an interval of 90°, and are rod-shaped.

The upwardly open space 241 formed on the diffusion plate 240 extends to the extension parts 248 from the central part 246. As shown in FIG. 7, the first processing gas flows into the central part 246 through the introductive tube 220, moves along inner paths of the extension parts 248 and spreads toward the outside of the diffusion plate 240 after ascending the fringe face 244 that is provided to both the sides and ends of the extension parts 248. In this embodiment, since the diffusion unit 200 has a plurality of rod-shaped extension parts 248, the first processing gas is widely spread out over a first space 622. In addition, as the processing gas flows laterally and reaches the ends of the extension parts 248, the diffusion unit 200 is able to prevent the deposition rate of the processing gas from being lowered in a region of the wafer W directly under the diffusion plate 240. The sizes and fringe heights of the extension parts may be modified in accordance with the size of the wafer W, deposition uniformity, and other factors.

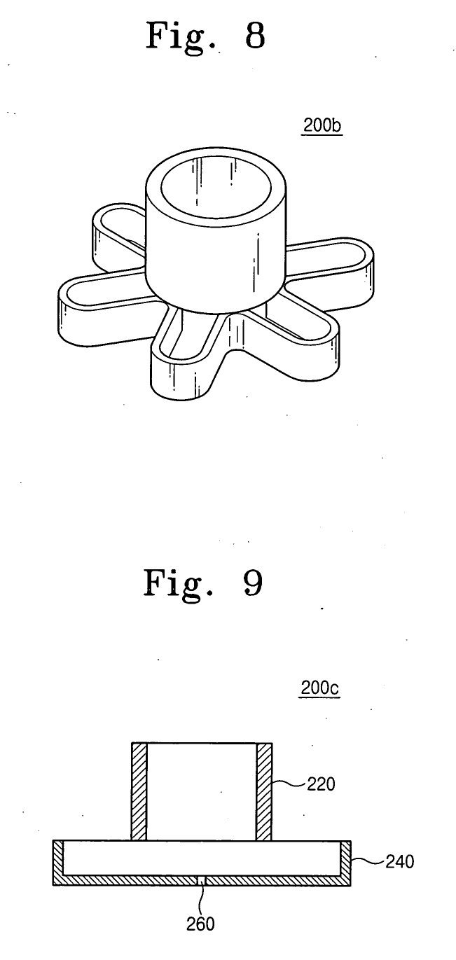

While diffusion unit 200 is shown in FIG. 4 with four extension units 248, the diffusion unit may also have three or five extension as shown in the extension units 200a and 200b in FIGS. 7 and 8. It is preferable for the number extension units 248 to be two through eight, with the most preferred number being three through six. If the number of the extension units 248 is one, it is impossible for the first processing gas to be spread over around the diffusion plate 240. If the number of the extension units 248 is larger than nine, it makes the diffusion plate structure complicated and may be disadvantageous to providing sufficient spaces between each of the extension units 248. Further, when the central part 246 of the diffusion plate 240 is wide, the diffusion unit 200d shown in FIG. 9 may include diffusion plate 240 in which one or a plurality of holes 260 are formed in the central part 246.

The diffusion plate 240 may be directly coupled to the chamber 10 with the diffusion plate 240 spaced from the top wall 12 of the chamber 10 a predetermined distance. In this embodiment, the processing gas flows directly into the upwardly open space 241 of the diffusion plate 240 without use of an introductive tube 220.

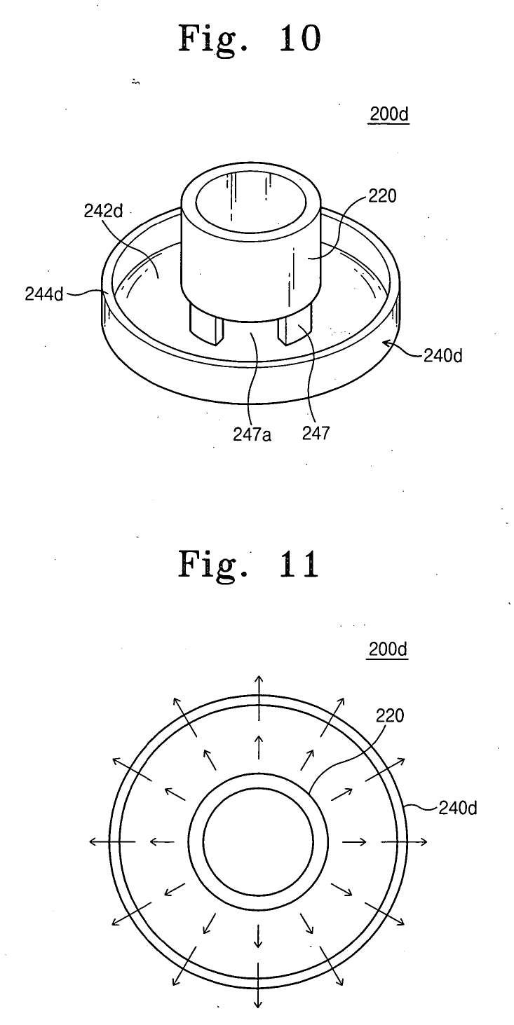

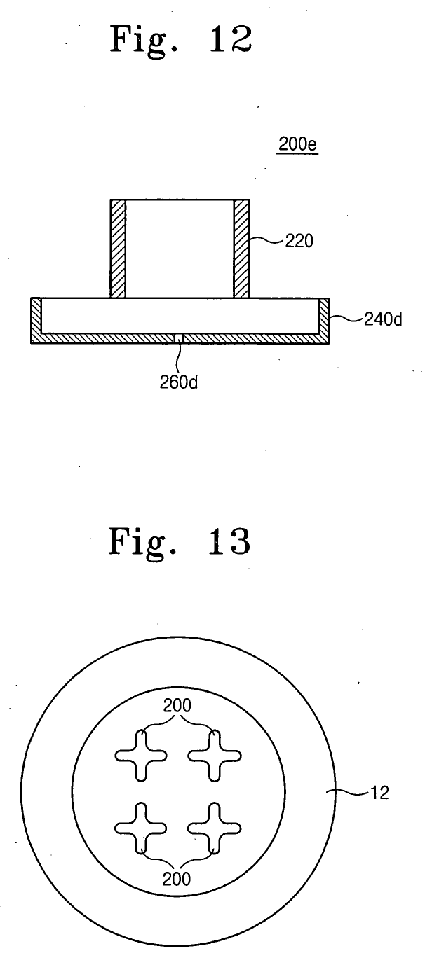

FIG. 10 is a perspective diagram illustrating another diffusion unit 200 shown in FIG. 4. Referring to FIG. 10, a diffusion plate 240d has of a round-shaped bottom plane 242d and a fringe face 244d extending upward from the edge of the bottom plane 242d. At the center of the bottom plane 242d, protrusions 247 extend upward to be coupled with the introductive tube 220. The protrusions 247 are spaced at predetermined intervals from each other, providing passages 247a for the processing gas. As illustrated in FIG. 11, the first processing gas flowing into the interspaces between the protrusions 247 from the introductive tube 230 reaches the edge of the diffusion plate 240d. After then, the first processing gas ascends the fringe face 244d and then spreads over and around the diffusion plate 240d. When the diffusion unit 200d, shown in FIG. 10, is used in the apparatus, it may reduce the deposition rate at the region of the wafer W directly under the diffusion plate 240d. In order to prevent such degradation of the deposition rate, as illustrated in FIG. 12, pluralities of holes 260d may be provided in the central region of the diffusion plate 240d.

The distance from the bottom of the ejection unit 100 to the top wall 12 of the chamber 10 is of sufficient length to enable the first processing gas to be ejected over the wafer W after being fully diffused in the first introductive space 122. The distance from the bottom of the ejection unit 100 to the top wall 12 of the chamber 10 combined with the diffusion unit 200 is preferably longer than about a quarter (¼) of a diameter of the wafer W. For example, when the diameter of the wafer W is 150 mm, the distance from the ejection unit 100 to the top wall 12 of the chamber 10 may be set at about 40 mm.

A plurality of diffusion units may also be employed in the first introductive space 122 as shown in FIG. 13, which is bottom plan view showing the bottom of the top wall 12 of the chamber 10 and the plurality of diffusion units 200. The plurality of diffusion units 200 may be disposed in a polygonal pattern, which is helpful for enabling the processing gas to be spread out wider and for preventing the degradation of the deposition rate at the region of the wafer W directly under each diffusion unit 200. With the plurality of diffusion units 200, processing gases collide in the spaces between the diffusion units 200, thereby generating particles. Otherwise, the simplicity of a single diffusion unit 200 may prevent the generation of particles.

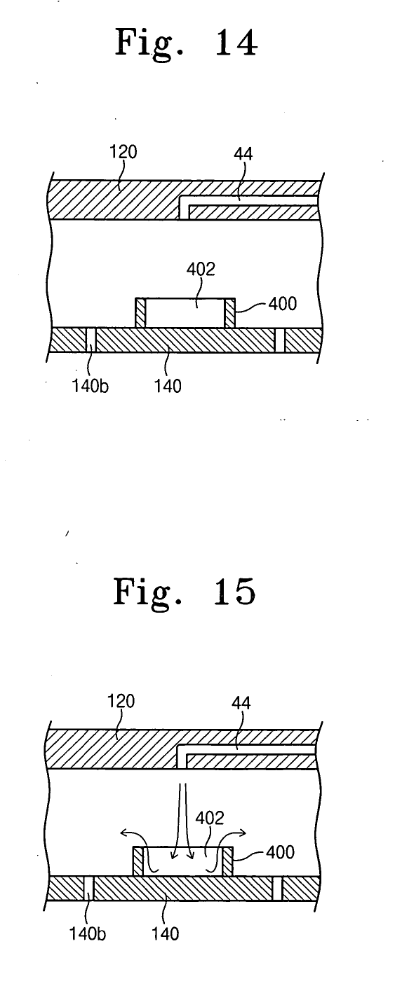

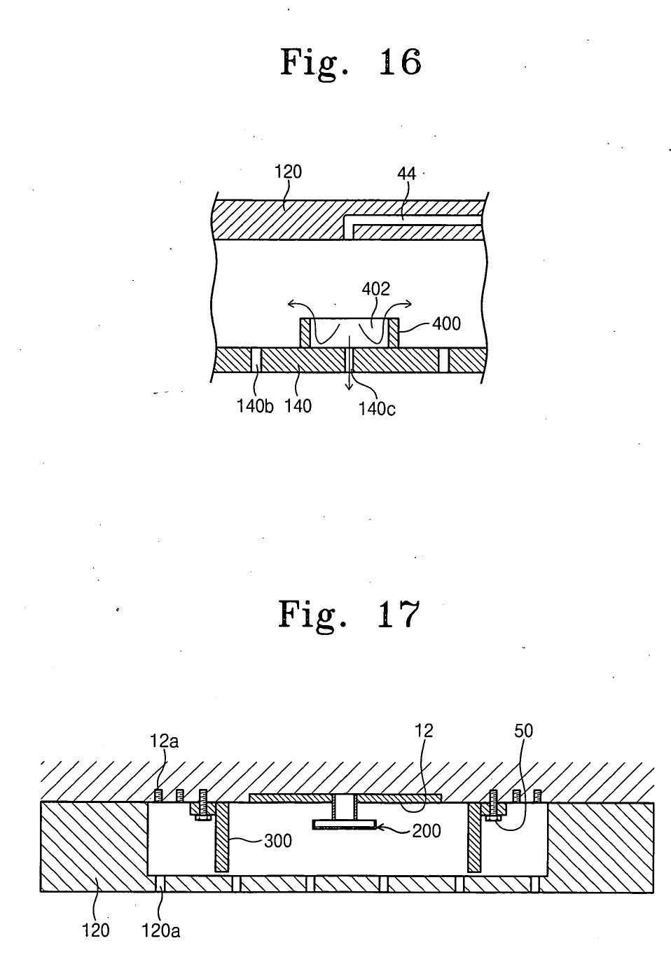

A supply line 44 is installed within the first ejection plate 120, through which the second processing gas flows from the second conduit 45. The location of the supply line 44 somewhat limits the arrangement of the first holes 120a in the first ejection plate 120. An outlet of the supply line 44 is located at the center of the bottom of the first ejection plate 120. As illustrated in FIG. 14, a ring-shaped projection unit 400 is located opposite to the outlet of the supply line 44 on the second ejection plate 140. The projection unit 400 is provided to help the second processing gas spread within the second introductive space 142. An upwardly open space 402 is formed at the center of the projection unit 400. As illustrated in FIG. 15, the second processing gas ejected into the space 402 of the projection unit 400 through the supply line ascends the sidewalls of the projection unit 400 and then spreads outward from the projection unit 400. As selectively illustrated in FIG. 16, a hole 140c may also be included in a region of the second ejection plate 140 opposite to the supply line 44 for ejecting a portion of the second processing gas through the second ejection plate 140. Further, the diffusion unit 200 used in the first introductive space 122, may be also disposed in the second introductive space 142 instead of the projection unit 400.

If the second ejection plate 140 is made of a stainless steel, it would be damaged from reaction with the first and second processing gases supplied downward onto the second ejection plate 140. According to an embodiment, the chamber 10 is made of a stainless steel, and the first and second ejection plates 120, 140 are made of aluminum in order to prevent the reaction with the processing gases. When the processing time of the deposition process becomes lengthy, supplemental film materials may adhere to the bottom of the second ejection plate 140. The film materials adhering to the bottom of the second ejection plate 140 would fall downward onto the second ejection plate 140, thereby adversely affecting the deposition process on wafer W. Thus, the bottom surface of the second ejection plate 140 is roughened for the purpose of preventing the adhesive materials from easily detaching and falling onto the second ejection plate 140. The roughened surface finish is accomplished by applying a sand burst or a metal organic chemical-mechanical polishing to the surface.

On the other hand, the temperature of the processing gas in the gas supplier 30 should be regulated at a constant level in order to obtain a uniform thickness of deposition over the entirety of the wafer W that is continuously treated through various processing steps. However, the temperature of the processing gas in the gas supplier 30 varies in accordance with a heater disposed therein, processing pressure, the amount of gas to be used, a distance between the ejection unit 100 and the wafer W, and other factors. In order to maintain the processing gas at a constant temperature in the gas supplier 30 through with various processing conditions, the deposition apparatus 1 includes a temperature control unit 500 for regulating the temperature of the gas supplier 30. The temperature control unit 500 includes a cooling sheet 540 and a heating sheet 520. The temperature control unit 500 is disposed on the top of the gas supplier 30, in order to prevent the holes of the first and second ejection plates 120 and 140 from being limited to their optimum arrangement. For instance, as illustrated in FIG. 1, the cooling sheet 540, as a cooling line through which a coolant flows, is provided on the top wall 12 of the chamber 10. The heating sheet 520 is disposed on the cooling sheet 540, being heated by the heater. The positions of the heating and cooling sheets, 530 and 540, are interchangeable.

A typical gas supplier 30 is configured only to conduct the deposition process for a wafer of a predetermined size. Therefore, if the process is carried out for a wafer larger than the wafer of a predetermined size, a deposition rate at the edge of the wafer is highly reduced. To the contrary, if the process is carried out for a wafer smaller than the wafer of a predetermined size, the processing gas is more dissipated. An embodiment herein provides a means of prosecuting the deposition process at a required deposition rate for various-sized wafer, without dissipating the processing gas. As an example, an intercepting unit 300 is provided in the gas supplier 30. The intercepting unit 300 is disposed in the first introductive space 122, restricting the diffusion range of the first processing gas. FIG. 17 is a cross-sectional diagram showing the interrupting unit 300 installed in the first introductive space 122. The interrupting unit 300 is ring-shaped, having a flange protruding outward at the top end thereof. The interrupting unit 300 is affixed within the first introductive space 122 by means of joining devices such as screws inserted therein. At the top wall 12 of the chamber 10, holes 12a, into which screws 50 are inserted, are provided over a plurality of positions to enable the interrupting unit 300 to be positioned at various diameters in accordance with a size of the wafer W to be processed. The interrupting unit 300 extends downward to a height slightly less than vertical height of the first introductive space 122, and is thus spaced apart from the first ejection plate 120. By spacing the interrupting unit from the first ejection plate 120, damage due to differing thermal expansion rates is avoided. The interrupting unit 300 may also be provided in the second introductive space 142.

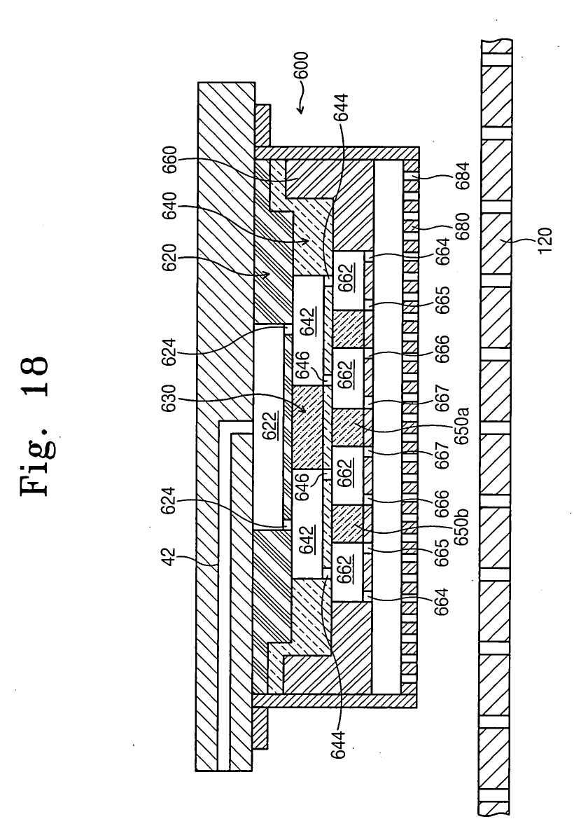

Next, another diffusion unit 600 that is modified from the diffusion unit 200 shown in FIG. 4 will be described. FIG. 18 is a cross-sectional diagram illustrating the diffusion unit 600. The structure of the deposition apparatus employing the diffusion unit 600 of FIG. 18 is similar to that employing the diffusion unit 200 of FIG. 4 but with a different the pattern. Referring to FIG. 18, the diffusion unit 600 is constructed in a distribution structure including pluralities of diffusion plates 620, 640, and 660 and partitions 630, 650a, and 650b. The diffusion plates 620, 640, and 660 are arranged to be stacked. In each diffusion plate, distribution holes, 624, 644, 646, 664, 665, 666, and 667, are formed to force the first processing gas to spread out gradually and widely. In spaces provided by the diffusion plates 620, 640, and 660, the one or plural partitions, 630, 650a, 650b, are positioned to minimize the collision with the first processing gases. Hereinafter, the structure of the diffusion unit 600 will be described in more detail. In this embodiment, the three diffusion plates 620, 640, and 660 are exemplarily implemented.

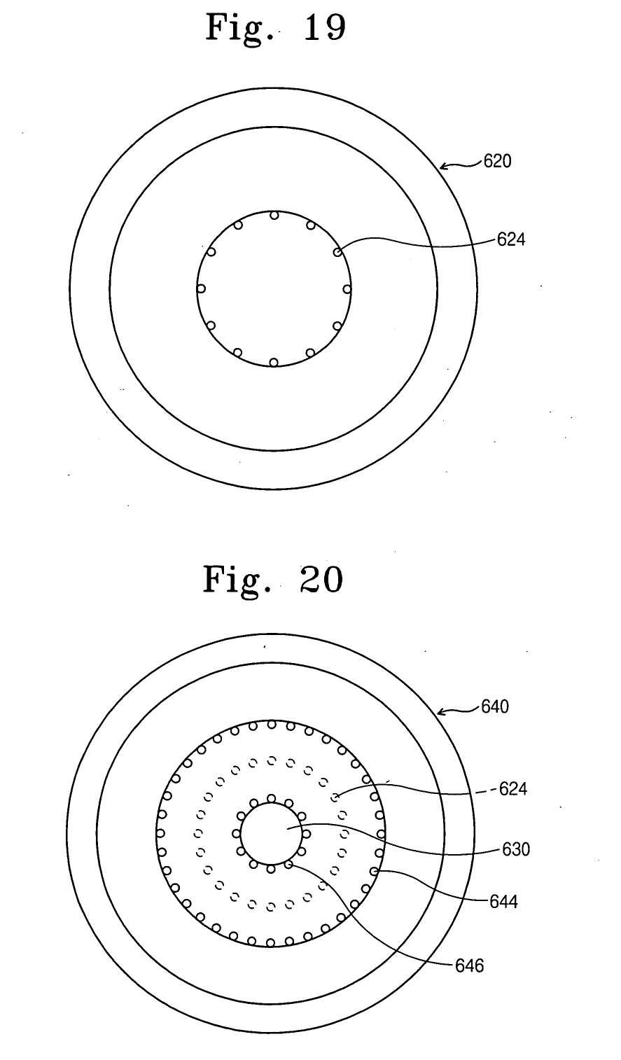

The diffusion unit 600 includes the first diffusion plate 620, the second diffusion plate 640, and the third diffusion plate 660 that are stacked on top of each other. FIG. 19 is a plan view illustrating the first diffusion plate 620. Referring to FIG. 19, the first diffusion plate 620 includes a round space with a first diameter at the center of the first diffusion plate, which when the first diffusion plate 620 is joined to the top wall 12 of the chamber 10 forms the first introductive space 122. The first processing gas ejected from the supply line 42 that is provided in the top wall 12 of the chamber 10 is first diffused in the first space 622. The first distribution holes 624 are located in a region of the first diffusion plate 620 at the lowest position under the first space 622. The first distribution holes 624 may be arranged in the form of circle as a whole.

FIG. 20 is a top plan view illustrating the second diffusion plate 640 and the partition 630. Referring to FIG. 20, the second diffusion plate 640 has a round space with a second diameter at the center of the second diffusion plate, which when the second diffusion plate 62 is joined with the first ejection plate 120 forms second space 642. The second diameter is larger than the first diameter. The processing gases ejected through the first distribution holes 624 are secondarily spread in the second space 642. When the processing gases collide with each other in the second space 642, particles generated from a reaction between the processing gases may be deposited on the first diffusion plate 620 or the second diffusion plate 640. The partition 630 is disposed at the center of the second space 642. The partition 630 is formed in a cylindrical shape. One end of the partition 630 contacts the bottom of the first diffusion plate 620 and the other end contacts the top face of the second diffusion plate 640. The partition 630 prevents the processing gases from colliding with each other while the processing gases partially flow. The second outer distribution holes 644 are disposed at the portion corresponding to the edge of the second space 642 in the second diffusion plate 640, and the second inner distribution holes 646 are disposed at the portion adjacent to the partition 630. The second inner distribution holes 646 and the second outer distribution holes 644 are arranged approximately in the form of circle. The processing gases flowing into the second space 642 from the first distribution holes 642 are divisionally spread into and out of the first space 622, and ejected downward through the second inner and outer distribution holes 646, 644. The partition 630 is preferably shaped such that a diameter of the circle formed by the second outer distribution holes 644 is three times that of the second inner distribution holes 646. It is also preferable for a distance between the second outer distribution hole 644 and the first distribution holes 624 to be identical to a distance between the second inner distribution holes 646 and the first distribution holes 624. This spacing between the sets of holes enables the processing gases to be spread out in evenly.

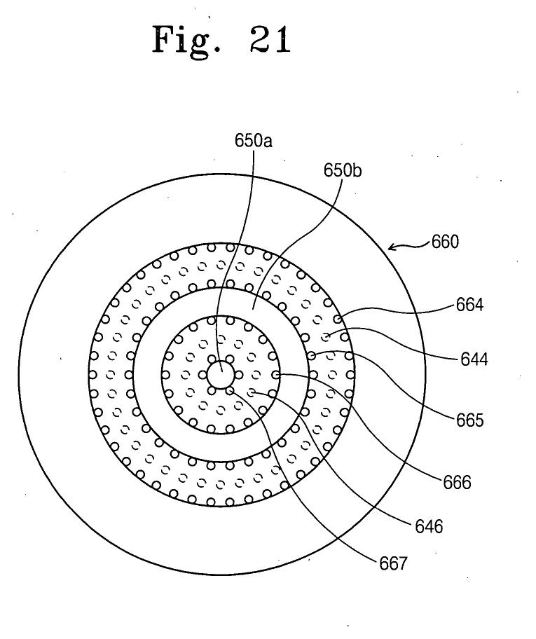

FIG. 21 is a top plan view illustrating the third diffusion plate 660 and the partitions 650a and 650b. Referring to FIG. 21, the third diffusion plate 660 has a round space with a third diameter at the center thereof, which when the third diffusion plate is joined to the second ejection plate 140 forms a third space 662. The processing gases ejected through the second inner and outer distribution holes 646 and 644 are spread within the third space 662.

In order to prevent the collision of the processing gases in the third space 662, inner and outer partitions 650a and 650b are provided in the third space 662. The inner partition 650a is formed in a cylindrical shape. One end of the inner partition 650a contacts the bottom of the second diffusion plate 640, while the other end contacts the top of the third diffusion plate 660. The inner partition 650a functions to prevent the processing gases from colliding with each other while the gases are flowing in the third space 662 from the second inner distribution holes 646. The outer partition 650b is spaced from the inner partition 650a in a predetermined distance and is ring-shaped. One end of the outer partition 650b contacts the bottom of the second diffusion plate 640, while the other end contacts the top of the third diffusion plate 660. The outer partition 650b is disposed under the center position between the second outer and inner distribution holes 644 and 646. The outer partition 650b functions to prevent the processing gas, which flows into the third space 662 through the second inner distribution holes 646, from colliding with the processing gas that flows into the third space 662 through the second outer distribution holes 644.

Third outer distribution holes 664 are formed at the portion corresponding to the edge of the third space 662, in the third diffusion plate 660, and outer intermediate distribution holes 665 are formed at the outside adjacent to the outer partition 650b. Inner intermediate distribution holes 666 are formed adjacent to the outer partition 650b, and third inner distribution holes 667 are formed adjacent to the inner partition 650a. The third outer distribution holes 664, the outer intermediate distribution holes 665, the inner intermediate distribution holes 666, and the third inner distribution holes 667 are each arranged in a circular pattern.

The processing gas flowing into the third space 662 through the second outer distribution holes 644 is ejected downward through the third outer distribution holes 664 and outer intermediate distribution holes 665. The processing gas flowing into the third space 662 through the second inner distribution holes 646 is ejected downward through the inner intermediate distribution holes 666 and the third inner distribution holes 667. The first processing gases are uniformly spread by having the same distances between the third outer distribution holes 664 and the outer intermediate distribution holes 665, between the outer intermediate distribution holes 665 and the inner intermediate distribution holes 666, between the inner intermediate distribution holes 666 and the third inner distribution holes 667 and between the third inner distribution holes 667 opposite to each other. A distance between the third outer distribution holes 664 and the second outer distribution holes 644 may be set to be the same as that between the outer intermediate distribution holes 665 and the second outer distribution holes 644. Also, a distance between the inner intermediate distribution holes 666 and the second inner distribution holes 646 may be set to be the same as that between the third inner distribution holes 667 and the second inner distribution holes 646.

While the former embodiment is described about the exemplary case with the same distances between the distribution holes 624, 644, 646, 664, 665, 666, and 667, the distances may be varied between the distribution holes 664, 665, 666, and 667 formed in the third diffusion plate 660 in order to make the deposition rate differ in accordance with positions on the wafer W. Further, while the former embodiment is implemented with the three diffusion plates 620, 640, and 660 as an example, two or four diffusion plates may be used. Even when more than four diffusion plates are provided, those skilled in the art may easily understand the configurations of the diffusion plates and partitions disposed under the third diffusion plate 660 from those patterns of the first, second, and third diffusion plates 620, 640, 660.

In the specified embodiment, both ends of the partitions, 630, 650a, 650b contact the diffusion plates 620, 640, 660 located at their upper and lower positions, but the partitions may also only contact with the diffusion plates with one end. The partitions, 630, 650a, 650b, may be positioned to contact the diffusion plates, 620, 640, 660 after being manufactured independent of the diffusion plates or may be each manufactured in a single body together with the diffusion plates as a whole.

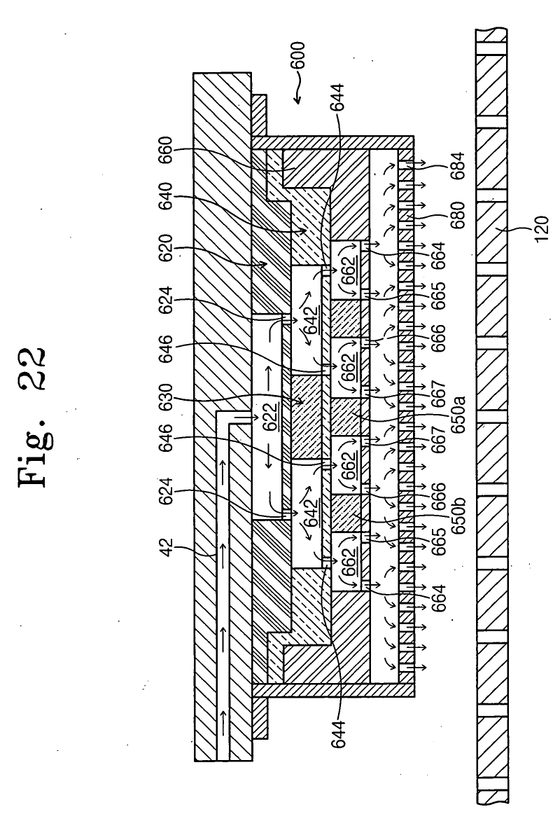

A porous plate 680 is disposed under the distribution structure. The porous plate 680 is spaced apart from the third diffusion plate 660 a predetermined distance, providing a fourth space 682 between the porous plate 680 and the third diffusion plate 660. The processing gas ejected downward through the third diffusion plate 660 is further diffused in the fourth space 682. Since holes are closely formed over the porous plate 680, the first processing gas flowing into the fourth space 682 is uniformly spread in the introductive space 122. FIG. 22 is a diagram illustrating a flow of the processing gas in the diffusion unit 600 shown in FIG. 18.

In the former embodiment, the diffusion unit 600 includes the three diffusion plates and the holes, 624, 644, 646, 665, 666, 667, that are formed in the diffusion plates, 620, 640, and 660, to cause the first processing gas to spread wider as it goes down. But, the number of the diffusion plates and the positions of the holes may vary in accordance with varying sizes of the wafer W and processing conditions.

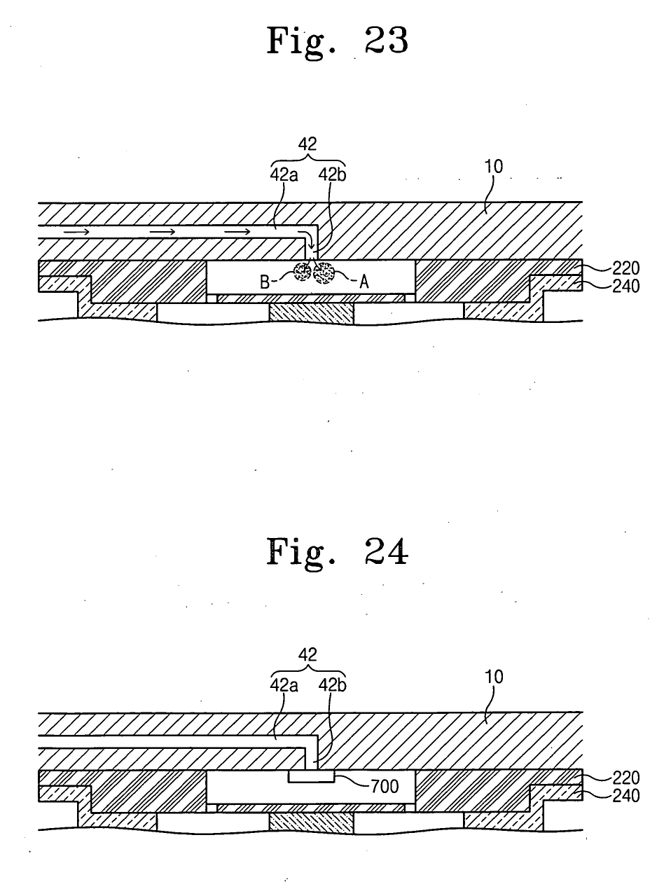

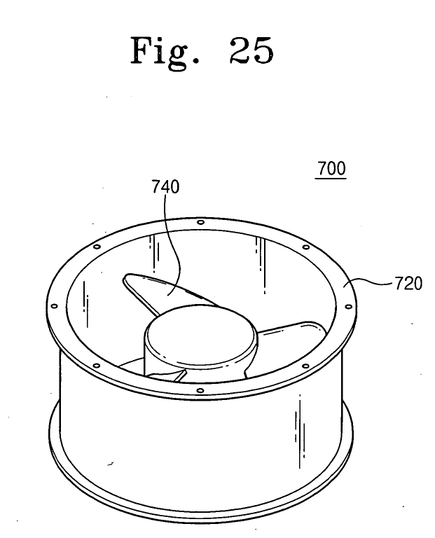

The first conduit 43 leads to the center or the side of the top of the chamber 10 in accordance with the disposition of peripheral constructions (not shown). When the first conduit 43 is connected to the side of the chamber 10, the supply line 42 is provided to the top wall 12 of the chamber 10 is composed of a horizontal line 42a extending to the center of the top wall 12 of the chamber 10, and a vertical line 42b extending from the horizontal line 42a, penetrating the bottom of the chamber 10. In this construction of the chamber 10, since the horizontal line 42a is relatively longer than the vertical line 42b, the processing gas is more ejected toward a region A that is opposite to a region B, as shown in FIG. 23. In order to prevent such an imbalanced ejection, referring to FIG. 24, a distributor 700 is coupled to the terminal of the vertical line 42b to make the first processing gas uniformly eject therefrom. FIG. 25 is a perspective diagram exemplarily illustrating the distributor 700 shown in FIG. 24. Referring to FIG. 25, the distributor 700 is configured in a fan, being composed of a cylindrical body 720, and plural wings 740 disposed in the body 720. The wings 40 are fixedly positioned within the body 720 and the processing gas is supplied downward along the surfaces of the wings 740. Selectively, the wings 740 may rotate within the body 720 to enable the processing gas to be more widely spread.

While the embodiments described above use two kinds of the processing, other variations are available. For instance, a singularity of processing gas may use a single ejection plate in the ejection unit 100, or three kinds of processing gases may use three ejection plates in the ejection unit 100. In addition, even when a plurality of processing gases are used therein in accordance with the kinds of processing gases and processing conditions, a single ejection plate may be used in ejection unit 100.

Although the present invention has been described in connection with the embodiments of the present invention illustrated in the accompanying drawings, it is not limited thereto. It will be apparent to those skilled in the art that various substitution, modifications and changes may be thereto without departing from the scope and spirit of the invention.

As described above, the deposition apparatus according to embodiments is able to conduct a uniform deposition process over the entire region of the wafer, to improve a deposition rate by maintaining a proper spacing between the wafer and the ejection unit and to advance the reliability of the sensing margin in a ferroelectric memory device during longer process times.

Further, the deposition apparatus according to embodiments prevents particles (or byproducts) from being generated by reactions of the processing gases because it is includes a structure preventing collision between the processing gases while the processing gases are diffused through the diffusion unit.

Moreover, the deposition apparatus may be configured in the simplified structure with the supply line in the ejection plate, optimizing the arrangement of the distribution holes in the ejection plate.

In addition, the deposition apparatus may be applicable to conducting a deposition processes for various-sized wafers because it may include an interrupting unit to regulate the range of diffusion of the processing gas in the first introductive space.

1. A semiconductor device manufacturing apparatus comprising:
a reaction chamber;
a wafer support;
an ejection unit having an ejection plate in a bottom portion of the ejection unit and ejection holes in the ejection plate, the bottom portion of the ejection plate spaced apart from a top wall of the reaction chamber to form a first space; and
a diffusion unit positioned below a first gas supply line to diffuse a first gas supplied to the space,
wherein the diffusion unit includes a planar diffusion plate having upwardly extending flanges forming an upwardly open space below the gas supply such that first gas from the first gas supply line flows into the upwardly open space and ascends the upwardly extending flanges to diffuse the first gas from the first gas supply into the first space.

2. The apparatus of claim 1, wherein the planar diffusion plate with upwardly extending flanges includes:
a central portion; and
a plurality of laterally extending portions extending laterally from the central portion,
wherein the central portion is positioned beneath the gas supply to cause the first gas from the first gas supply line to flow to the central portion and then outwardly through the laterally extending portions.

3. The apparatus of claim 2, wherein the plurality of laterally extending portions are arranged equally around the central portion.

4. The apparatus of claim 2, wherein the plurality of laterally extending portions is three through eight laterally extending portions.

5. The apparatus of claim 2, wherein each laterally extending portion is generally rod-shaped.

6. The apparatus of claim 2, wherein the central portion includes a hole to supply gas downwardly through the diffusion plate.

7. The apparatus of claim 1, wherein the planar diffusion plate with upwardly extending flanges is generally round-shaped.

8. The apparatus of claim 1, wherein the planar diffusion plate with upwardly extending flanges is a plurality of planar diffusion plates with upwardly extending flanges.

9. The apparatus of claim 1, further comprising an interrupting unit located in the first space to restrict a range of diffusion of gas entering the first space.

10. The apparatus of claim 9, wherein the interrupting unit is ring-shaped and spaced apart from the diffusion unit a predetermined distance.

11. The apparatus of claim 9, wherein the interrupting unit is adjustably positionable within the first space to correspond to varying sizes of wafers.

12. The apparatus of claim 1, wherein the ejection unit comprises an aluminum alloy.

13. The apparatus of claim 1, wherein the ejection unit comprises:
a first ejection plate with first ejection holes in a bottom portion of the first ejection plate, the bottom portion of the first ejection plate spaced apart from a top wall of the reaction chamber to form a first space; and
a second ejection plate with second ejection holes in a bottom portion of the second ejection plate, the second ejection plate disposed under and on the first ejection plate and the bottom portion of the second ejection plate spaced apart from a bottom surface of the first ejection plate to form a second space.

14. The apparatus of claim 13, wherein the bottom portion of the first ejection plate includes a second gas supply line to supply a second gas to the second space,
wherein the second ejection plate includes a ring-shaped projection on the bottom portion of the second ejection plate positioned below the second gas supply line in the first ejection plate.

15. The apparatus of claim 14, wherein the ring-shaped projection includes and upwardly facing opening such that second gas from the second gas supply line in the first ejection plate will flow into the upwardly facing opening and then diffuse outward after ascending an inner sidewall of the ring-shaped projection.

16. The apparatus of claim 14, further comprising:
a first gas supply connected to the first gas supply line, the first gas supply includes plumbum (Pb), zirconimum (Zr) and titanium (Ti); and
a second gas supply connected to the second gas supply line, the second gas supply includes oxygen (O).

17. The apparatus of claim 1, wherein a bottom surface of the ejection unit is positioned within 20 mm from a wafer mounted on the wafer support.

18. The apparatus of claim 17, wherein the diffusion unit is located a distance from a bottom of the ejection unit that is greater than a quarter of a diameter of a wafer to be processed.

19. The apparatus of claim 1, further comprising:
a temperature control unit regulating the temperature of the gas in the ejection unit positioned above the ejection unit.

20. A semiconductor device manufacturing apparatus comprising:
a reaction chamber;
a wafer support;
a first gas supply line to supply a first processing gas; and
a gas diffusion unit to diffuse the first processing gas over the wafer support,
wherein the gas diffusion unit comprises:
a first diffusion plate spaced apart from a top wall of the reaction chamber to form a first space, the first diffusion plate including first distribution holes through first diffusion plate located near an edge of the first space, and
a second diffusion plate spaced apart from a bottom surface of the first diffusion plate to form a second space that is larger than the first space, the second diffusion plate including second outer distribution holes through the second diffusion plate located near and edge of the second space.

21. The apparatus of claim 20, where in the fist and second spaces are cylindrically shaped.

22. The apparatus of claim 21, wherein the second space includes a partition at the center of the second space,
wherein the second diffusion plate includes second inner distribution holes located adjacent to the partition.

23. The apparatus of claim 22, wherein the first distribution holes are disposed over a space between the second inner distribution holes and the second outer distribution holes.

24. The apparatus of claim 22, wherein the first distribution holes, the second inner distribution holes and the second outer distribution holes are arranged in circular patterns,
wherein a diameter of the circle provided by the second outer distribution holes is about three times a diameter of the circle provided by the second inner distribution holes.

25. The apparatus of claim 22, wherein the diffusion unit further comprises:
a third diffusion plate disposed under the second diffusion plate to provide a third space larger than the second space;
a cylindrically shaped inner partition disposed at a center of the third space;
an outer partition surrounding the cylindrical inner partition in the third space;
third outer distribution holes through the third diffusion plate located near an edge of the third space;
third inner distribution holes through the third diffusion plate located adjacent to the inner partition;
third inner intermediate distribution holes through the third diffusion plate located inward from and adjacent to the outer partition; and
third outer intermediate distribution holes through the third diffusion plate located outward from and adjacent to the outer partition,
wherein fluid communication in the third space exists between the second outer distribution holes and both the third outer and third outer intermediate distribution holes, between the second inner distribution holes and both the third inner and third inner intermediate distribution holes.

26. The apparatus of claim 25, wherein the second outer distribution holes are located over a center of a space between the third outer distribution holes and the third outer intermediate distribution holes,
wherein the second inner distribution holes are located over a center of a space between the third inner distribution holes and the third inner intermediate distribution holes.

27. The apparatus of claim 20, further comprising a porous plate positioned below the diffusion unit.

28. The apparatus as set forth in claim 20, wherein the gas supplier further comprises:
an interrupting unit which restricts a range of diffusing the processing gas through the ejection holes, the interrupting unit being separably disposed in the space.

29. The apparatus of claim 28, wherein the first ejection plate includes a second gas supply line to supply a second processing gas into the second processing gas space,
wherein the second ejection plate includes a projection unit located below the second gas supply line to diffuse the second processing gas.

30. The apparatus of claim 29, further comprising:
a supply of first processing gas connected to the first gas supply line, the first processing gas includes plumbum (Pb), zirconium (Zr) and titanium; and
a supply of second processing gas connected to the second gas supply line, the second processing gas includes oxygen (O).

31. The apparatus of claim 20, wherein the first gas supply line comprises a horizontal line connected to an extem gas supply, and a vertical line extending from the horizontal line and including an outlet,
wherein the diffusion unit further comprises a fan shaped distributor adjacent to the outlet.
